(19) United States
(12) Patent Application Publication
(10) Pub. No.: US 2011/0240325 A1
(43) Pub. Date: Oct. 6, 2011

(54) Printed Wiring Board and Electronic Apparatus

(76) Inventors: Daigo Suzuki, Yokohama-shi (JP); Terunari Kanou, Hamura-shi (JP)

(21) Appl. No.: 13/034,495

(22) Filed: Feb. 24, 2011

(30) Foreign Application Priority Data
Mar. 31, 2010 (JP) 2010-084338

(51) Int. Cl. H05K 5/00; H05K 1/00

(52) U.S. Cl. 174/50; 174/250

(57) ABSTRACT

According to one embodiment, there is provided a printed wiring board including: a board body having a first surface and a second surface opposite thereto, a product part defined in the board body, at which a wiring pattern is formed; an end part defined in the board body, at a position separated from the product part; a connecting part defined in the board body, through which the product part and the end part are connected; and a coating-material applied on the first surface of the board body along the connecting part.

### CROSS-REFERENCE TO RELATED APPLICATION(S)

This application is based upon and claims the benefit of priority from Japanese Patent Application No. 2010-084338, filed on Mar. 31, 2010, the entire contents of which are incorporated herein by reference.

### FIELD

Embodiments described herein relate generally to a printed wiring board and an electronic apparatus.

### BACKGROUND

Printed circuit boards (PCBs) used in electronic apparatuses, such as personal computers, and printed wiring boards (PWBs) configured by mounted-components have various shapes depending on the finished-products thereof. However, before being supplied to a mounting line, each PWB is formed as a part of a shape in which a main piece to be formed into a finished-product of a PWB and an end member (waste member) are combined. The main piece and the end member are connected by perforated members, and the end member is separated from the main piece as a product part by punching.

For example, JP-S62-098795-A discloses a technique of processing the material without making a metal pressing impact on a coating film during outline machining.

However, in the related art, stress applied to the product part during processing is not taken into consideration.

One surface of the board exemplified in JP-S62-098795-A to be put on a mold is flat. However, for example, to accomplish high-density interconnection, wiring patterns may be provided on both surfaces of the product part. In this case, air-gaps may be generated between the mold and the board body by irregularities due to the patterns. For example, when the air-gaps are positioned in the boundary between the main piece and the end member, the board body cannot sufficiently be supported on the mold and thus bends. This may result in damage of the product part.

### BRIEF DESCRIPTION OF THE DRAWINGS

A general architecture that implements the various feature of the present invention will now be described with reference to the drawings. The drawings and the associated descriptions are provided to illustrate embodiments of the present invention and not to limit the scope of the present invention.

FIG. 1 schematically illustrates an electronic apparatus according to an embodiment.

FIG. 2 illustrates electronic components mounted on a printed wiring board according to the embodiment before punched.

FIG. 3 illustrates a connecting part of the printed wiring board according to the embodiment.

FIG. 4 sectionally illustrates the printed wiring board according to the embodiment.

FIG. 5 illustrates a process operation according to the embodiment performed before a punching-cut operation.

FIG. 6 illustrates the punching-cut operation.

FIG. 7 illustrates a modification of the embodiment.

FIG. 8 illustrates a printed wiring board according to a second embodiment.

FIG. 9 illustrates a printed wiring board according to a third embodiment.

FIG. 10 illustrates a printed wiring board according to a fourth embodiment.

### DETAILED DESCRIPTION

In general, according to one embodiment, there is provided a printed wiring board including: a board body having a first surface and a second surface opposite thereto, a product part defined in the board body, at which a wiring pattern is formed; an end part defined in the board body, at a position separated from the product part; a connecting part defined in the board body, through which the product part and the end part are connected; and a coating-material applied on the first surface of the board body along the connecting part.

Hereinafter, embodiments are described in detail with reference to the drawings.

(Configuration of Electronic Apparatus)

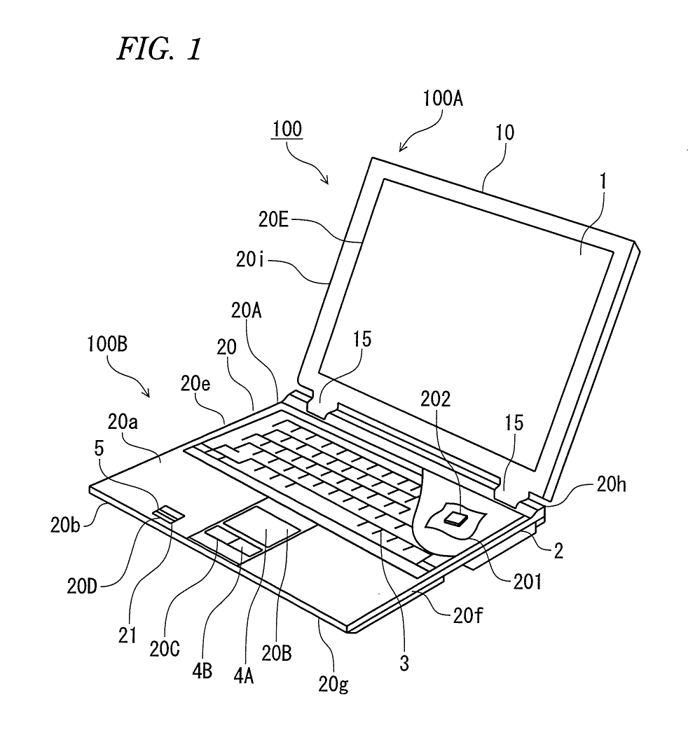

FIG. 1 schematically illustrates an electronic apparatus according to an embodiment in which a notebook type personal computer is exemplified.

A personal computer (electronic apparatus) 100 according to the present embodiment includes a display portion 100A and a body portion 100B. The display portion 100A and the body portion 100B are openably connected to each other by a hinge portion 15. The body portion 100B has a lower casing 20. The lower casing 20 (casing) houses a function portion 2 having a printed wiring board 201 (printed wiring board), on which electronic components such as a central processing unit (CPU) and a memory are mounted, and that processes information.

The lower casing 20 has a top surface 20a, a bottom surface 20b, a left side surface 20e, a right side surface 20f, a front surface 20g, and a rear surface 20h. The lower casing 20 houses a character input portion 3, such as a keyboard, for inputting characters and commands, a track pad 4A serving as a pointing device, a decision switch 4B for inputting selection and decision commands, and a fingerprint reading portion 5 used to authenticate users. Openings 20A to 20D are formed in the top surface 20a. A depression portion 21 is formed around the opening 20D. The character input portion 3 is exposed from the opening 20A. The track pad 4A is exposed from the opening 20B. The decision switch 4B is exposed from the opening 20C. The fingerprint reading portion 5 is exposed from the opening 20D.

The display portion 100A has an upper casing 10. The upper casing 10 houses an image display portion 1 including a liquid crystal panel or the like for displaying characters, images and the like. The upper casing 10 has a front surface 20i. An opening 20E is formed in the front surface 20i. The image display portion 1 is exposed from the opening 20E.

A printed wiring board 201 housed in the personal computer 100 can have various shapes depending on a mounted component in the casing and the product size thereof. Before loaded into a mounting line, the printed wiring board 201 is manufactured as a part of a plate-like member in which a product part (to be formed into the printed wiring board 201) and an end member are combined, in view of enhancing workability and manufacturability. After supplied to the mounting line, the product part and the end member are separated from each other by punching.

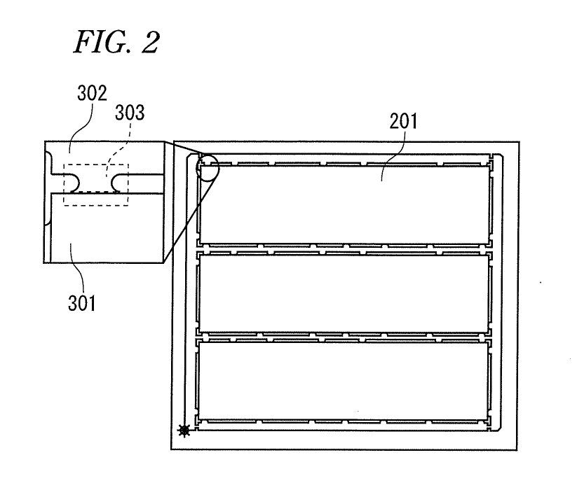

Hereinafter, the configuration of the printed wiring board 201 before loaded into the mounting line according to the present embodiment, and the configuration of a separation operation in the mounting line are described with reference to FIGS. 2 to 9.

(Configuration of Printed Wiring Board)

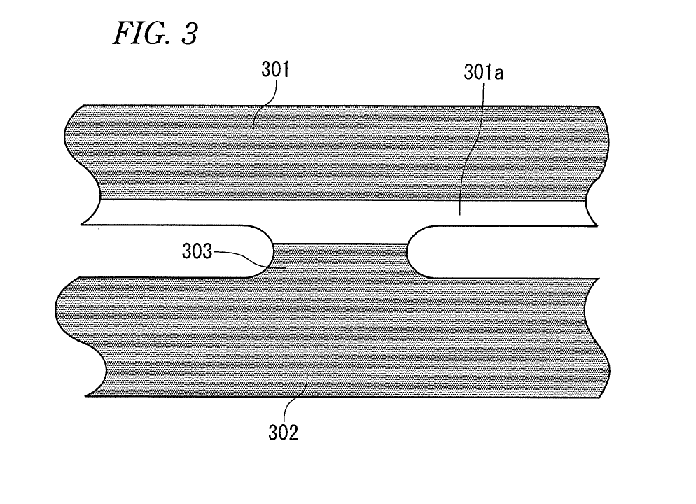

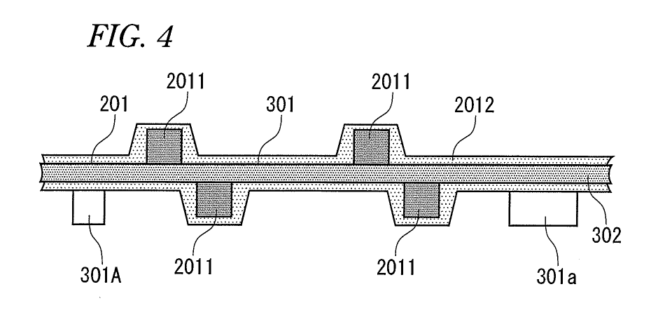

First, the configuration of the printed wiring board 201 housed in the personal computer 100 according to the present embodiment is described with reference to FIGS. 2 to 4. FIG. 2 illustrates the printed wiring board 201 before punched. FIG. 3 illustrates a connecting part of the printed wiring board 201. FIG. 4 sectionally illustrates the printed wiring board 201.

As illustrated in FIGS. 2 to 4, the printed wiring board 201 includes a product part 301 (product part) on which an electronic component (not shown) is mounted, an end member 302 (end part) provided around the product part 301 to have an air-gap between the product part 301 and the end member 302, and a connecting part 303 (connecting part) which connects the product part 301 to the end member 302.

As illustrated in FIG. 3, a silk 301a (coating-material) is applied over the product part 301 and the end member 302 on the printed wiring board 201 according to the present embodiment. The silk 301a is applied around the connecting part 303. In the present embodiment, the silk 301a is applied to at least an area extending over the product part 301 and the connecting part 303. The “silk” is a coating-material such as oil-based ink using, e.g., a volatile organic solvent, and aqueous ink that uses water as a solvent so as to be water-resist after dried.

As illustrated in FIG. 4, a silk 301A showing characters indicating an electronic component mounting area and/or product information is provided on the printed wiring board 201. The silk 301a to be provided around, e.g., the connecting part 303 is applied onto the same surface as that to which the silk 301A is applied. Such configuration can be accomplished by a single silk-screen printing operation. Consequently, a manufacturing process can be simplified.

As illustrated in FIG. 4, a wiring pattern 2011 and a resist 2012 are provided on each of both surfaces of the printed wiring board 201. Plural irregularities exist on each surface of the printed wiring board 201. The wiring pattern 2011 is provided at a position distant from the connecting part 303, i.e., a position distant from an edge part of the printed wiring board 201.

In the printed wiring board 201 according to the present embodiment, upon completion of a process of mounting an electronic component in a state in which the product part 301 and the end member 302 are connected to each other by the connecting part 303, the connecting part 303 is cut off by a punching-cut operation to separate the product part 301 and the end member 302 from each other.

As illustrated in FIGS. 3 and 4, in the printed wiring board 201, a region in which the silk 301a is provided, i.e., a region whose thickness is larger than that of the board body of the printed wiring board 201 is provided along a punching orbit (corresponding to a punching-cut end) in a punching-cut operation. As illustrated in FIG. 4, the thickness of this region is substantially equal to that of the wiring pattern 2011 provided on each of both surfaces of the printed wiring board 201. That is, the film thickness, i.e., the height of the silk 301a applied around the connecting part 303 of the printed wiring board 201 is substantially equal to the height of the wiring pattern 2011.

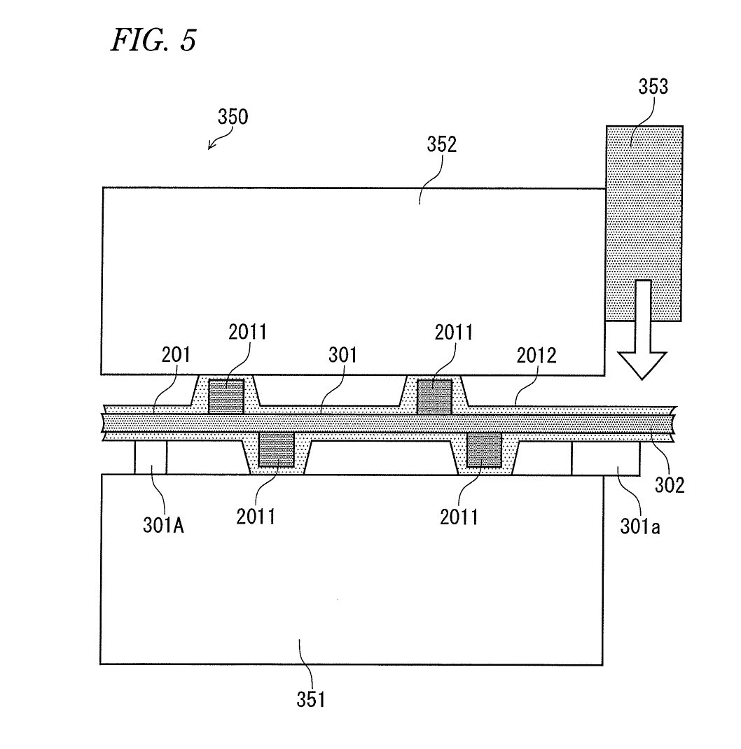

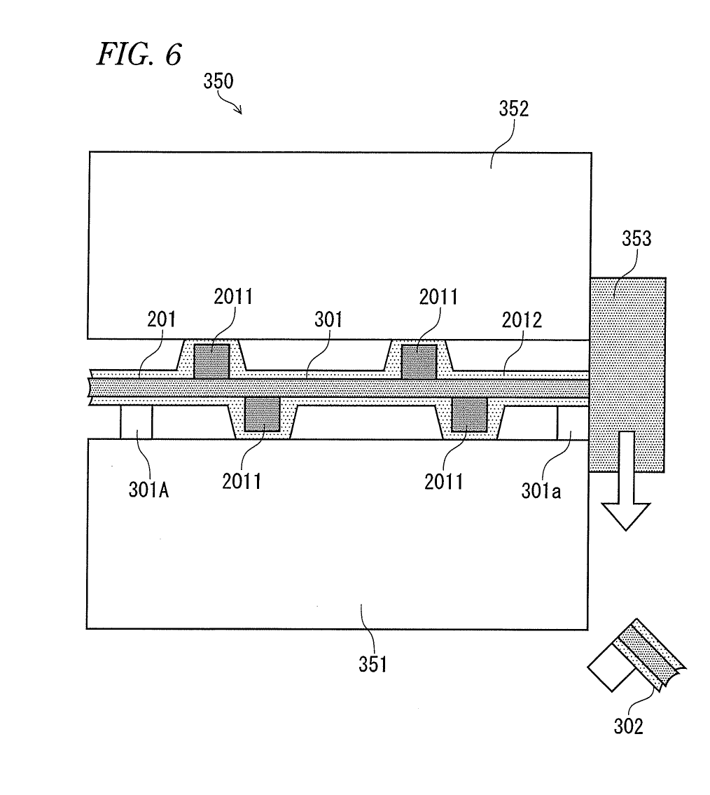

Thus, in the printed wiring board 201, the silk 301a is provided along the punching orbit in the punching-cut operation. Consequently, the silk 301a abuts on the mounting surface of the mold, on which the silk 301a is put in the progression of punching. Accordingly, the wiring-board can be restrained from being bent in a punching direction. Hereinafter, a punching-cut operation for the printed wiring board 201 according to the present embodiment is described with reference to FIGS. 5 and 6.

In the punching-cut operation, first, the printed wiring board 201 is put on the mounting surface 351 of the mold 350. According to the present embodiment, the printed wiring board 201 is put thereon such that the surface of the printed wiring board 201, on which the silk 301a of the printed wiring board 201 and the mounting surface 351 of the mold 350 face each other. In the present embodiment, the silk 301a is applied on the one surface of the printed wiring board 201. However, the silk 301a can be provided on the both surfaces of the printed wiring board 201. Thus, alignment to be performed, when the printed wiring board 201 is placed on the mounting surface 351 of the mold 350, can be facilitated.

Next, in the punching-cut operation, as illustrated in FIG. 5, a pressing plate 352 of the mold 350 is lowered to fix the printed wiring board 201 between the pressing plate 352 and the mounting surface 351 of the mold 350. At that time, the connecting part 303 and the end member 302 are placed outside the end parts of the mounting surface 351 of the mold 350 and the pressing plate 352, i.e., outside a region of the mold 350 to be punched by a punch portion 353.

Next, in the punching-cut operation, as illustrated in FIG. 6, the punch portion 353 of the mold 350 is dropped in the punching direction to separate the product part 301 and the end member 302 from each other. In a state where the printed wiring board 201 is set in the punching mold 350, the mounting surface 351 of the mold 350 is separated from the printed wiring board 201 at least a distance equal to the thickness of the wiring pattern 201. For example, when the silk-portion 301a is not applied along the punching orbit, a region around the punching orbit is not sufficiently supported by the mounting surface 351 of the mold 350. Thus, when the punching-cut is performed, the printed wiring board 201 bends in the punching direction. Consequently, damages, such as cracks, can be generated in the printed wiring board 201.

According to the present embodiment, the silk 301a functioning as a support member is provided between the mounting surface 351 of the mold 350 and the printed wiring board 201 at the region around of the punching orbit. Consequently, the production yield of the printed wiring board 201 is enhanced, and the reliability of the product can be increased.

According to the present embodiment, the silk 301a is applied along the punching orbit. Thus, for example, it is unnecessary to provide a conduction pattern in the apparatus and to check whether cutting is normally performed at the punching-cut through electrical testing. And, whether cutting is normally performed can be determined and checked through visual inspection. Accordingly, reduction in the manufacturing cost, and enhancement of working efficiency in the punching-cut operation can be achieved.

For example, as illustrated in FIG. 4, when no silk 301a is left on the printed wiring board 201 after the punching-cut, a worker can determine that cutting is not normally performed. When the silk 301a is left on the printed wiring board 201 after the punching-cut, the worker can determine that cutting is normally performed.

In the printed wiring plate 201 according to the present embodiment, after the punching-cut, whether cutting is normally achieved can be determined by the visual inspection of the region around the connecting part 303, in which the silk 301a is applied.

An example of applying the silk 301 along the punching orbit has been described herein. However, as long as a material serves as a support member in the region around the punching orbit, such a material can be used as the material applied to the board according to the embodiment. For example, a dummy wire, a dummy component, or an elastic member such as a member formed of a rubber material can be provided in a region around the punching orbit. Preferably, such a support member has a height substantially equal to the thickness of the wiring pattern 2011. As long as the board can be restrained from bending in the punching direction, the support member can be provided to be lower than the wiring pattern 2011. For example, when the film thickness of the resist 2012 is set to be large in a region around the punching orbit, it is difficult to uniform the film thickness thereof. However, in the printed wiring board 201 according to the present embodiment, the film thickness of the resist 2012 can be uniformed using a material such as the silk 301a.

In the present embodiment, the position of the silk 301a is set so that a part of the silk 301a is placed outside the end parts of the mounting surface 351 of the mold 350 and the pressing plate 352. however, the position of the silk 301a is not limited thereto. The silk 301a can be set so that the entire surface of the silk 301a faces the mounting surface 351 of the mold 350.

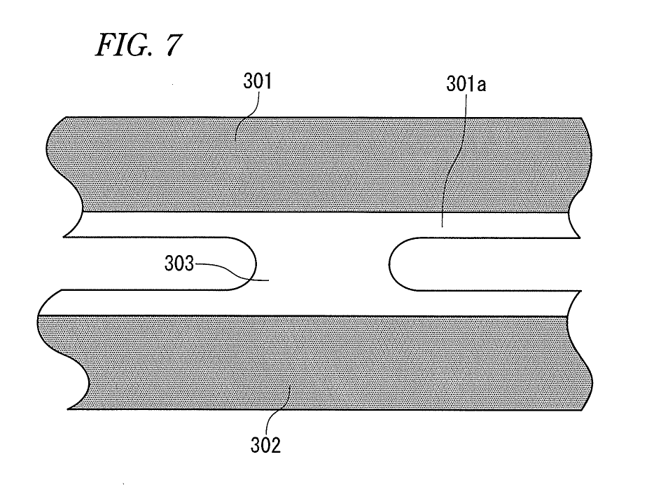

Next, a modification of the embodiment is described hereinafter with reference to FIG. 7. FIG. 7 illustrates the printed wiring board 201 according to the modification. Other components of the portable computer 100 are substantially similar to those illustrated in FIG. 1.

The modification differs from the above embodiment in the shape of the silk 301a applied to the printed wiring board 201. In the modification, the silk 301a is applied to an area extending over the product part 301 and the end member 302 around the connecting part 303. Such a shape of the applied silk 301a increases an allowable degree of deviation of the mounting position of the printed wiring board 201 from the mounting surface 351 of the mold 350. That is, if the mounting position of the printed wiring board 201 deviates toward the inside of the mold 350 when the pressing plate 352 is set or when a punching-cut operation is performed, an appropriate treatment will be performed.

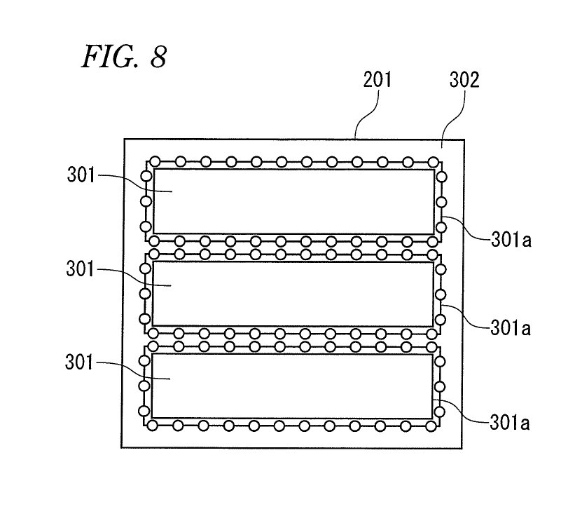

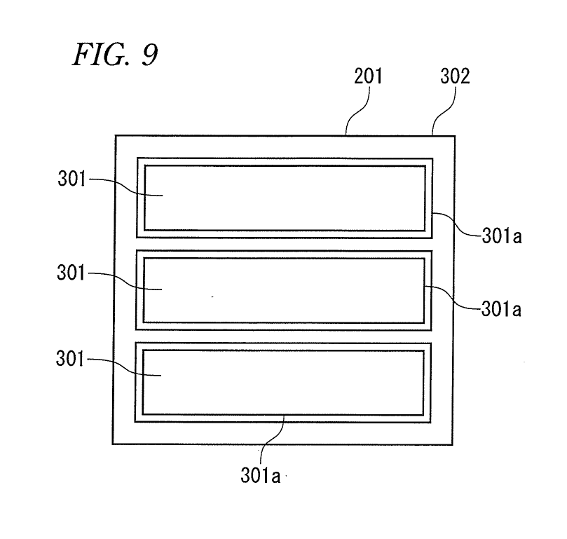

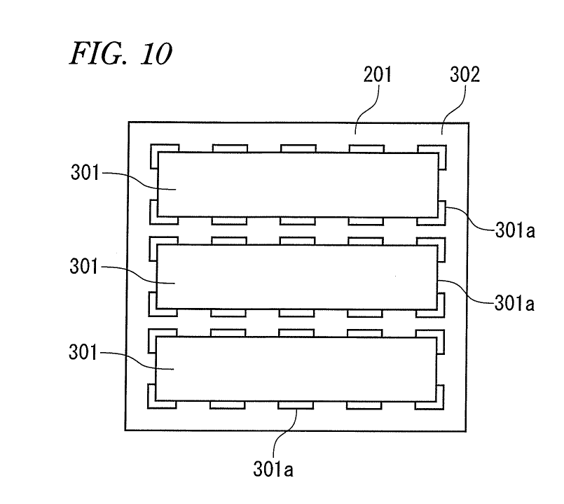

Next, the portable computer 100 serving as an electronic apparatus according to each of other embodiments is described hereinafter with reference to FIGS. 8 to 10. FIG. 8 illustrates the printed wiring board 201 according to a second embodiment. FIG. 9 illustrates the printed wiring board 201 according to a third embodiment. FIG. 10 illustrates the printed wiring board 201 according to a fourth embodiment. Each component having functions which are the same as or similar to those of the associate component of the portable computer 100 according to the first embodiment is designated with the same reference numeral. Thus, the description of such components is omitted. The second to fourth embodiments differ from the first embodiment in the shape of the printed wiring board 201. Each of the portable computers 100 according to the second to fourth embodiments has an external appearance substantially the same as that illustrated in FIG. 1.

The casing of each of the portable computers 100 according to the second to fourth embodiments houses the printed wiring board 201. The printed wiring boards 201 according to the second to fourth embodiments are not subjected to routing to be performed before the punching-cut. In the printed wiring board 201 according to the second embodiment, hole-portions are provided on the punching orbit by drilling. In the printed wiring boards 201 according to the third and fourth embodiments, hole-portions or the like are not machined on the punching orbit. In the printed wiring board 201 according to the fourth embodiment, the silk 301a is discretely applied onto each product part. With such a configuration, advantages similar to those of the printed wiring board according to the first embodiment can be obtained. In addition, the silk 301a is more emphasized, so that the visual inspection is facilitated.

In the foregoing description, the first to fourth embodiments and the modification thereof have been described. However, the embodiments are not limited thereto. Components according to the first to third embodiments and the modifications thereof can be implemented by being appropriately combined with one another.

The embodiments are applicable not only to a portable computer, but also to various electronic apparatuses, e.g., a hard disk drive, a digital camera, a digital video camera, and a personal digital assistant.

What is claimed is:

1. A printed wiring board comprising:
a board body having a first surface and a second surface opposite thereto,
a product part defined in the board body, at which a wiring pattern is formed;
an end part defined in the board body, at a position separated from the product part;
a connecting part defined in the board body, through which the product part and the end part are connected; and
a coating-material applied on the first surface of the board body along the connecting part.

2. The printed wiring board of claim 1,
wherein the wiring pattern is provided at a position distant from the connecting part.

3. The printed wiring board of claim 2,
wherein the coating-material is applied to have a thickness the same with a height of the wiring pattern.

4. The printed wiring board of claim 3,
wherein the coating-material is provided by a silk-screen printing.

5. The printed wiring board of claim 4,
wherein the coating-material is provided on the second surface of the board body at the connecting part.

6. An electronic apparatus comprising:
a casing;
a board body to be housed in the casing, the board body having a first surface on which a wiring pattern is provided and a second surface opposite thereto;
a resist applied onto the first surface of the board body; and
a coating-material applied onto the resist along an edge part of the first surface of the board body.

7. The electronic apparatus of claim 6,
wherein the wiring pattern is provided at a position distant from the edge part.

8. The electronic apparatus of claim 7,
wherein the coating-material is applied to have a thickness the same with a height of the wiring pattern.

9. The electronic apparatus of claim 8,
wherein the coating-material is provided by a silk-screen printing.

10. The electronic apparatus of claim 9,
wherein the coating-material is provided on the resist on the second surface of the board body.
